(19) United States
(12) Patent Application Publication
(10) Pub. No.: US 2009/0004840 A1
(43) Pub. Date: Jan. 1, 2009

(54) Method of Creating Molds of Variable Solder Volumes for Flip Attach

(76) Inventors: Matthew J. Farinelli, Bronx, NY (US); Steven Cordes, Yorktown Heights, NY (US); Donna S. Nielsen, Yorktown Heights, NY (US); Samuel Roy McKnight, New Paltz, NY (US); Jay S. Chey, Ossining, NY (US); Peter A. Gruber, Mohegan Lake, NY (US); Joanna Rosner, Cortlandt Manor, NY (US)

Correspondence Address: Frank Chau, Esq.;F.CHAU & ASSOCIATES, LLC, 130 Woodbury Road, Woodbury, NY, 11797, US

(21) Appl. No.: 11/769,389

(22) Filed: Jun. 27, 2007

(51) Int. Cl. H01L 21/441; H01B 13/00

(52) U.S. Cl. 438/616; 216/18; 257/E21.476

(57) ABSTRACT

A method for fabricating a solder transfer mold includes masking a substrate with a masking agent. A pattern is transferred to the substrate mask. The masked substrate is etched until cavities of a first volume are formed. The cavities of the first volume are selectively coated. The masked substrate is etched until cavities of a second volume are formed.

### BACKGROUND OF THE INVENTION

1. Technical Field

The present disclosure relates to flip attach and, more specifically, to methods of creating molds of variable solder volumes for flip attach.

2. Discussion of the Related Art

In the process of manufacturing electronic equipment, semiconductor devices, such as integrated circuits (ICs) are often encased in a protective package and mounted onto a printed circuit board (PCB) or other electronic device.

Conventionally, semiconductor devices may be mounted onto a PCB using a series of thin wire interconnects. However, as semiconductor devices become smaller and more complex, the wire interconnects must become thinner and closer together. Many modern semiconductor devices are so small and complex that wire interconnects are no longer practical. Accordingly, other methods for chip mounting have been developed.

Flip chip mounting methods are used to mount a semiconductor device without the need for wire connections. In flip chip mounting, bumps of solder are formed on the chip's connection pads during wafer processing. The chip may then be inverted such that the solder bumps directly contact the PCB or other associated external circuitry. Then, in a process called controlled collapse chip connection (C4), the solder bumps are reflowed and electrical connection is achieved. Electrically-insulating adhesive may then be used to underfill the space between the chip and the PCB to provide a stronger mechanical connection.

Solder may be applied to a semiconductor chip to form interconnects. Methods for applying the solder bumps to the chip have been developed. For example, solder may be applied by evaporation through a shadow mask, electroplated into a Riston opening, or screen printing. Other approaches include injection molded solder (IMS) and direct solder ball attach.

For example, the surface of the wafer may be screened with solder paste before the chip die is cut. However, the solder paste, which generally includes flux and solder alloy particles, may lack a consistent and uniform composition, especially as the size of the solder bumps decreases to accommodate smaller chips. Particular care may be given to provide for a highly uniform and consistent solder paste, however, such care generally comes at a high cost. Moreover, another problem with using solder paste screening techniques in modern high density devices is the reduced pitch between bumps. Since there is a large reduction in volume from a screened paste to the resulting solder bump, the screen holes must be significantly larger in diameter than the final bumps. Thus stringent dimensional control of the bumps makes the solder paste screening technique impractical for applications in high density devices.

More recently developed injection molded solder (IMS) techniques attempt to solve these problems by dispensing molten solder instead of solder paste. According to these methods, a transfer mold having an array of cavities is filled with injected solder. The mold is then disposed over a semiconductor chip or chip packaging substrate such that the filled cavities align with the points of electrical contact on the chip. A combination of heat and gas pressure is applied to transfer the solder pattern onto the chip. Methods for IMS are described in U.S. Pat. Nos. 5,244,143; 6,056,191; and 6,105,852, the disclosures of which are hereby incorporated by reference in their entirety.

Transfer molds are generally made of glass or polymeric substrates. A masking material may then be deposited on the mold and a pattern of holes may be formed on the mask. The layout of the patterned holes is determined by the footprint of the chip that is to receive the solder bumps. The mask is then etched to form the cavities and the mask is then removed. Because most etch processes are isotropic and have a constant etch rate in all directions, the diameter of the holes in the mask and the spacing between the holes in the mask determine the diameter, pitch and etch depth of the cavities that are formed during etching.

### SUMMARY

A method for fabricating a solder transfer mold includes masking a substrate with a masking agent. A pattern is transferred to the substrate mask. The masked substrate is etched until cavities of a first volume are formed. The cavities of the first volume are selectively coated. The masked substrate is etched until cavities of a second volume are formed.

A method for fabricating a solder transfer mold includes covering a substrate having anisotropic etching properties with a masking layer. The masking layer is patterned to create a plurality of openings of at least two different sizes. The substrate is etched through the patterned mask to generate a plurality of cavities of at least two different volumes.

A solder mold includes a substrate. The substrate includes a plurality of cavities for holding solder to be transferred to an integrated circuit. The plurality of cavities includes cavities of at least two different volumes.

A method for applying solder bumps directly to an integrated circuit includes filling a plurality of cavities within a solder mold with solder. The solder mold is placed in proximity with the integrated circuit. The solder is transferred from the pluralities of the cavities to the integrated circuit. The solder mold includes a substrate and the plurality of cavities and the plurality of cavities include cavities of at least two different volumes.

A method for fabricating a solder transfer mold having solder cavities of multiple different volumes includes placing multiple alternating layers of a first protective material and a second protective material on a substrate. The following etch steps are repeated: a first protective material etch is performed, a second protective material etch is performed, and a substrate etch is performed. The number of alternating layer pairs is equal to the number of etch step repetitions and is equal to the number of different volumes.

A method for generating a solder mold includes etching a first set of cavities of a first volume in a solder mold substrate. The first set of cavities continue to be etched while etching a second set of cavities of a second volume. The second volume is smaller than the first volume.

### BRIEF DESCRIPTION OF THE DRAWINGS

A more complete appreciation of the present disclosure and many of the attendant advantages thereof will be readily obtained as the same becomes better understood by reference to the following detailed description when considered in connection with the accompanying drawings, wherein:

FIG. 1 is a flow chart showing a method for fabricating a transfer mold according to an exemplary embodiment of the present invention;

FIG. 2 illustrates an isotropic etching process for etching solder cavities using a selective deposition of metal according to an exemplary embodiment of the present invention;

FIG. 3 illustrates a process for creating variable pitch solder molds using selective deposition of a polymer material as the etch barrier according to an exemplary embodiment of the present invention;

FIG. 4 illustrates a process for creating variable pitch solder molds using anisotropic etching properties of silicon according to an exemplary embodiment of the present invention;

FIGS. 5(A-M) illustrate a process for creating variable pitch solder molds according to an exemplary embodiment of the present invention; and

FIG. 6 is a flow chart illustrating the process shown in FIGS. 5(A-M).

### DETAILED DESCRIPTION OF THE DRAWINGS

In describing the exemplary embodiments of the present disclosure illustrated in the drawings, specific terminology is employed for sake of clarity. However, the present disclosure is not intended to be limited to the specific terminology so selected, and it is to be understood that each specific element includes all technical equivalents which operate in a similar manner.

Exemplary embodiments of the present invention seek to provide injection molded solder (IMS) techniques that allow for solder bumps of varying volumes within a single transfer mold. A single transfer mold may thereby be used to transfer solder bumps of different diameter and pitch without having to use multiple transfer molds. For example, some transferred solder bumps may have a diameter of 4 thousandths of an inch (mils) and a pitch of 8 mils (4-on-8), while other transferred solder bumps may have a diameter of 3 mils and a pitch of 6 mils (3-on-6), and still other transferred solder bumps may have a diameter of 2 mils and a pitch of 4 mils (2-on-4), etc.

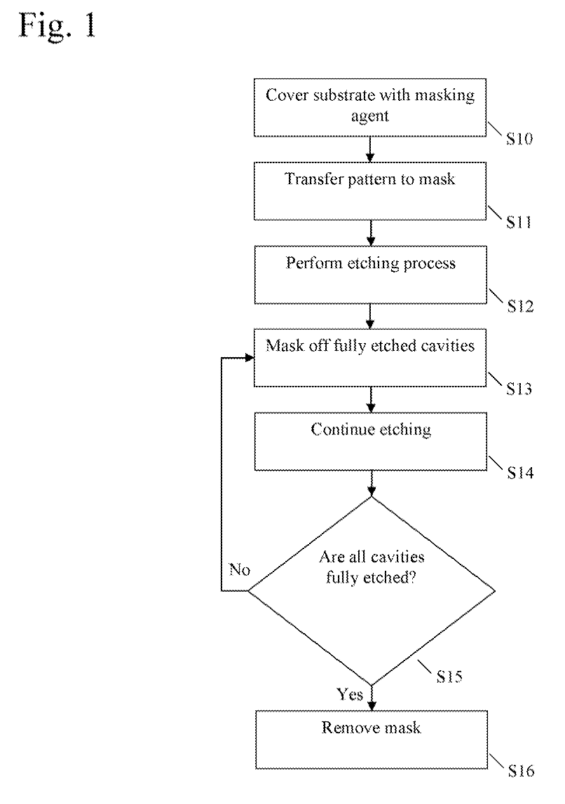

FIG. 1 is a flow chart showing a method for fabricating a transfer mold according to an exemplary embodiment of the present invention. First, a mold substrate, for example, a substrate of glass, silicon or a polymeric substrate, may be masked with a masking agent (Step S10). The desired pattern for the solder bumps may be transferred onto the masking agent (Step S11). The pattern may include features having any desired combination of diameter and pitch. For example, some features may be 4-on-8, some may be 3-on-6 and some may be 2-on-4, etc. Pattern transfer may be executed using known techniques, for example, photolithographic techniques. After the desired pattern has been transferred, an etching process may be performed (Step S12). For example, the masked mold substrate may be wet etched. Etching may continue until the cavities with the smallest volume, for example, the 2-on-4 cavities, are fully formed. At this point, cavities having larger volumes may be less than fully etched. The fully formed cavities may then be masked off (Step S13). After the fully formed cavities are masked, etching may continue on all of the cavities that remain unmasked (Step S14). Etching may continue until the cavities with the next-smallest volume, for example, the 3-on-6 cavities, are fully formed. The fully formed cavities may then be masked off and etching may continue again. The steps of masking off the fully formed cavities (Step S13) and etching the remaining cavities (Step S14) may be repeated until the cavities with the largest volume, for example, the 4-on-8 cavities, are fully formed. After all cavities are fully formed (Yes, Step S15), the masking layers may be removed (Step S16).

Many available techniques may be used to mask off the fully formed cavities to prevent over-etching and allow for multiple cavities of various sized on a single mold substrate. According to one exemplary embodiment of the present invention, fully formed cavities of the mold may be selectively coated with a metal layer to prevent over-etching. Accordingly, a metal layer may be used as a sacrificial mask to prevent over-etching in fully formed cavities.

According to another exemplary embodiment of the present invention, a polymer may be deposited into fully formed cavities of the mold to prevent over-etching. The polymer may be defined by either standard photolithographic techniques, for example, photo-imageable polymide, or by selective removal using laser ablation.

According to another exemplary embodiment of the present invention, the mold substrate may be made of anisotropic crystalline silicon. When using such a substrate, the process is self-limiting and the diameter of the hole of a single masking layer will automatically determine the final depth of the fully formed cavity. Accordingly, a single mask and a single etching operation may be sufficient to create fully formed varieties of varying sizes and volumes.

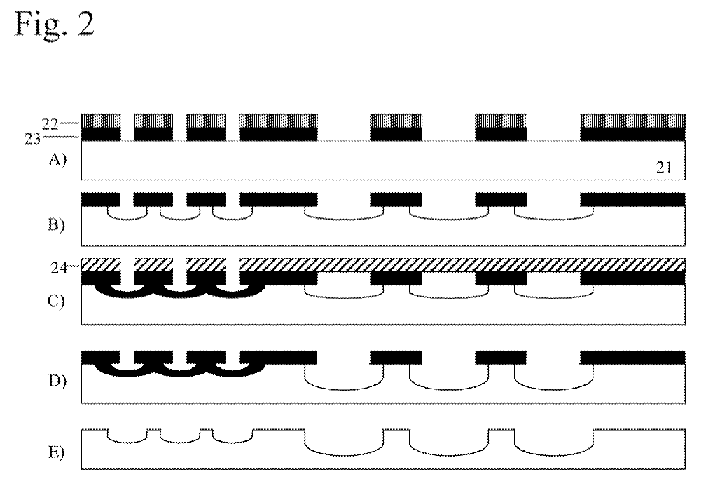

FIG. 2 illustrates an isotropic etching process for etching solder cavities using a selective deposition of metal according to an exemplary embodiment of the present invention. Accordingly, a multiple pitch IMS solder mold may be created by using selective deposition of a metal masking layer to protect fully formed cavities from over-etch while etching continues on cavities with larger volumes. As seen in FIG. 2, a substrate 21 is used. The substrate 21 may be, for example, a glass substrate. A metal film 23, for example, a copper film, is formed on the substrate 21. The metal film may be formed on the substrate 21 using known techniques such as vapor deposition and/or sputtering. A photoresist layer 22 may be formed over the metal film 23 using known techniques such as spin coating. The photoresist layer 22 may then be patterned with the pattern of multiple features having a desired combination of diameter and pitch. Pattern transfer may be carried out using known techniques such as photolithography. The patterned photoresist layer 22 may then be etched using known etching techniques. FIG. 2A shows the IMS solder mold after etching of the resist layer 22 and the metal layer 23 have been accomplished.

Resist removal and wet isotropic mold etching may be performed. Etching may continue until the smallest cavities are fully formed. FIG. 2B shows the result of this step. After the smallest cavities are fully formed, the mold is aligned to a metal mask 24 to selectively mask the fully formed cavities. A metal film is then locally deposited inside the fully formed cavities and further mold etching in these locations is terminated. FIG. 2C shows the IMS solder mold after the metal film 23 has been locally deposited inside the fully formed cavities.

The metal mask 24 may be removed and etching may resume until the next-higher volume cavities are fully formed. In FIG. 2, only two different sized cavities are shown, however, any number of different sized cavities may be created by additional steps of masking fully formed cavities. FIG. 2D shows the IMS solder mold with the larger volume cavities fully formed. The metal layer 23 may finally be removed, for example, through wet etch removal. FIG. 2E shows the completed IMS solder mold with the metal layer 23 having been removed.

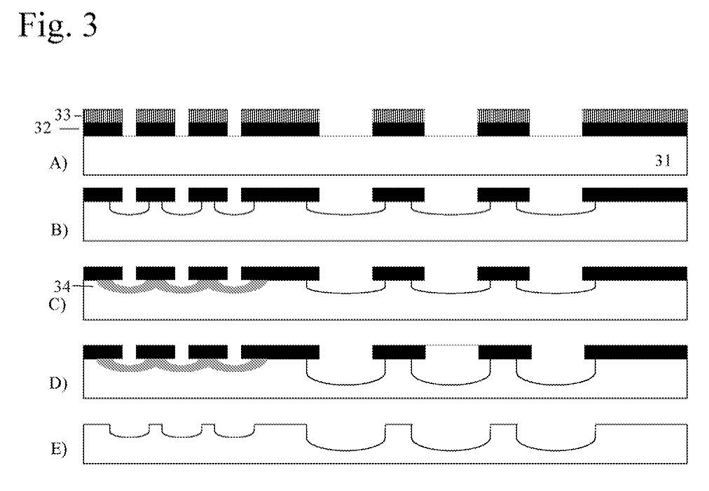

FIG. 3 illustrates a process for creating variable pitch solder molds using selective deposition of a polymer material as the etch barrier according to an exemplary embodiment of the present invention. As seen in FIG. 3, a substrate 31 is used. The substrate 31 may be, for example, a glass substrate.

As seen in FIG. 3, a metal film 32 may be formed on the substrate 31 using known techniques such as vapor deposition and/or sputtering. A resist layer 33 may be formed over the metal film 32 using known techniques such as spin coating. The resist layer 33 may then be patterned with the pattern of multiple features having a desired combination of diameter and pitch. Pattern transfer may be carried out using known techniques such as photolithography. The patterned resist layer 33 may then be etched using known etching techniques. FIG. 3A shows the IMS solder mold after etching of the resist layer 33 and the metal layer 32 have been accomplished.

Resist removal and wet isotropic mold etching may be performed. Etching may continue until the smallest cavities are fully formed. FIG. 3B shows the result of this step. After the smallest cavities are fully formed, the smallest cavities of the substrate 31 may be filled with a sacrificial polymer 34. The sacrificial polymer may be selected to be stable at the temperatures used to fill, transfer, and reflow. For example, the polymer may be polyimide. Alternatively, the fully formed cavities may be filled with any substance that is impervious to the substrate etching technique used. For example, the selected substance may be a metal that does not react with glass etchants. FIG. 3C shows the sacrificial polymer layer 34 filling the fully etched cavities.

Where the selected polymer 34 is curable, the polymer 34 may be cured to prevent over etching when etching continues. Etching may then resume until the next-higher volume cavities are fully formed. In FIG. 3, only two different sized cavities are shown, however, any number of different sized cavities may be created by additional steps of filling fully formed cavities with the polymer or other selected substances and, where appropriate, curing the polymer, and resuming etching. FIG. 3D shows the IMS solder mold with the larger volume cavities fully formed. The metal layer 32 may finally be removed, for example, through wet etch removal. A process technique may be used to remove the sacrificial polymer layer 34 or other protective substance from the cavities. For example, laser ablation may be used to remove the sacrificial polymer layer 34 or other protective substance. For example, plasma ashing, reactive ion etching (RIE) and/or chemical stripping may be used to remove the sacrificial polymer layer 34 or other protective substance. FIG. 3E shows the completed IMS solder mold with the metal layer 32 and the sacrificial polymer layer 34 having been removed.

The completed IMS solder mold may then be used to transfer solder onto a die by filling the cavities with solder and transferring the solder onto the die. Here, known solder transfer processes may be used.

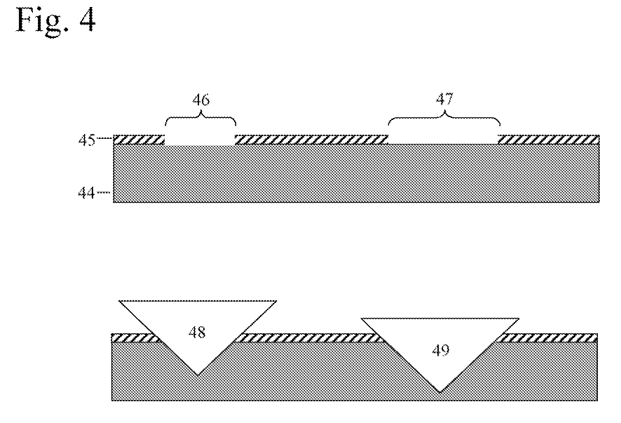

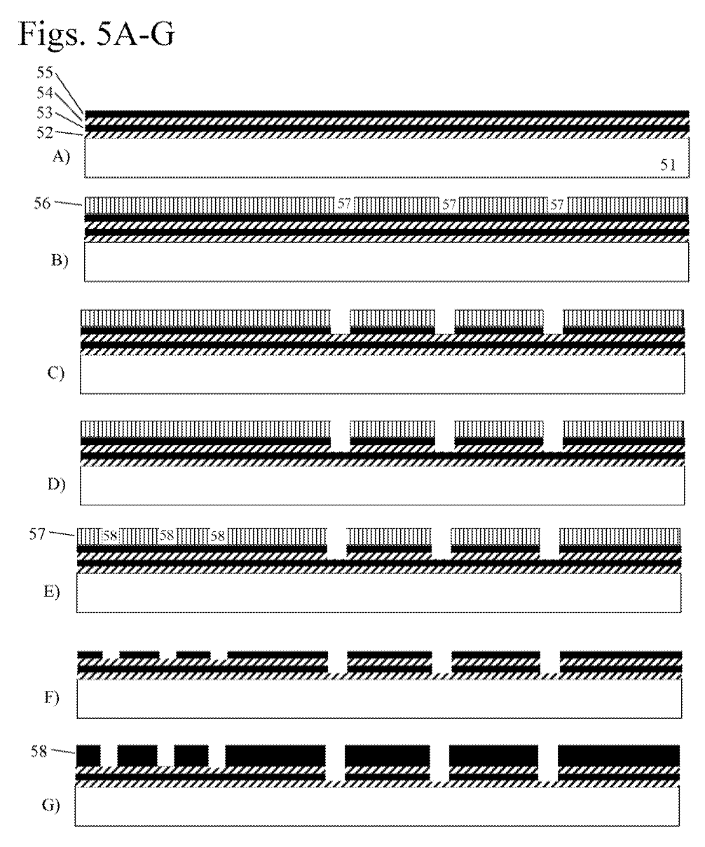

FIG. 4 illustrates a process for creating variable pitch solder molds using anisotropic etching properties of silicon according to an exemplary embodiment of the present invention. In FIG. 4, rather than using a glass substrate, a substrate of crystalline silicon, or another material with anisotropic etching properties may be used as a substrate for an IMS solder mold.

The substrate 44 may comprise, for example, a single silicon crystal with a (100) orientation. First, the crystal substrate may be oxidized to provide an oxidation layer 45. The oxidation layer 45 may be, for example, approximately 5000 Å thick. The oxidation layer 45 may then be patterned, for example, with square or rectangular features. The patterning may be accomplished, for example, using lithographic techniques. The patterned oxidation layer 45 may then be etched, for example, etched in BHF, to open one or more oxide windows 46 and 47 of varying sizes. For example, a smaller oxide window 46 may be 1 mil by 1 mil and a larger oxide window 47 may be 2 mil by 2 mil. Anisotropic wet etching may then be performed on the substrate 44 masked by the patterned oxidation layer 45. The wet etch may be performed, for example, using EPPW or KOH solution or any chemistry suited for anisotropic etching of silicon.

When the side of the square or rectangular features are aligned to the (110) direction of the wafer, the resulting etch cavities are pyramid shaped with four sides following the (111) plane. The resulting pyramid shaped cavities are self-limiting in size. Due to the anisotropic nature of the silicon substrate, the volumes of the resultant cavities are a direct result of the size and shape of the patterned opening. Accordingly, larger openings may result in deeper cavities. The triangles 48 and 49 in FIG. 4 represent the geometry of the resultant cavities for the given openings. The smaller opening 46 results in lesser substrate 44 penetration (shown with triangle 48) while the larger opening 47 results in greater substrate 44 penetration (shown with triangle 49). For example, the smaller opening 46 (1 mil by 1 mil) may result in a cavity with a volume of 0.236 mil³ while the larger opening 47 (2 mil by 2 mil) may result in a cavity with a volume of 1.886 mil³. Due to imperfect anisotropic etch, the actual pyramid volume may increase in size about 10% and this increase may be factored into the design of the oxide openings 46 and 47.

After the cavities have been formed, a final oxidation step may be performed to provide a protective oxide layer (not shown) over the substrate 44. Accordingly, cavities of various volumes may be obtained with a single fabrication process flow.

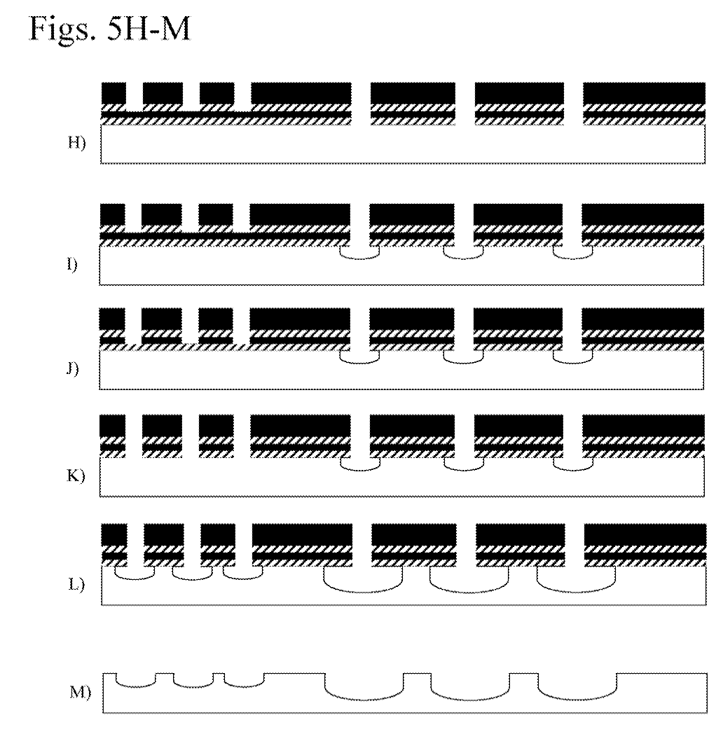

FIGS. 5(A-M) illustrate a process for creating variable pitch solder molds according to an exemplary embodiment of the present invention. First, a mold substrate 51, for example, made of glass, is covered with alternating layers of protective metal layers with varying etch sensitivities, for example, copper and chromium. The number of layers is determined by the number of different sized solder volumes. In the example shown, there are two different sized solder volumes, so there are accordingly two sets of alternating layers. Where more sized solder volumes are needed, more layers may be added and the disclosed process may be extrapolated to accommodate the additional layers.

As seen in FIG. 5A, the glass mold substrate 51 is covered by a first chromium layer 52, a first copper layer 53, a second chromium layer 54 and a second copper layer 55. More alternating layers may be used for implementations having volumes of more than two sizes.

Each copper layer may be approximately 500 to 5000 Angstroms thick. Each chromium layer may be approximately 100-200 Angstroms thick.

As seen in FIG. 5B, the alternating chromium and copper layers are covered by a first photoresist layer 56. The first photoresist layer 56 may be patterned to create openings for the volumes having the largest size. Here, the pattern is represented by the first openings 57. The first photoresist 56 and openings 57 together form a first photomask.

Again, it is noted that the alternating layers may be of materials other than copper and chromium as long as the layers have different etch sensitivities, however, as described herein, copper and chromium are illustrated to provide a simple example.

As seen in FIG. 5C, a first copper etch may be performed through the holes 57 of the first photoresist layer 56. The first copper etch should remove the top copper layer 55 under the holes 57. Then, as seen in FIG. 5D, a first chromium etch may be performed. The first chromium etch should remove the top chromium layer 54 under the holes 57. The first chromium etch may either be performed through the holes 57 of the first photoresist layer 56 or the first photoresist layer 56 may be removed and the first chromium etch may be performed through the holes in the first copper layer created during the first copper etch.

Then as seen in FIG. 5E, the first photoresist layer 56 may be removed, if it had not already been removed in the previous step, and a second photoresist layer 57 may be applied. The second photoresist layer 57 may then be patterned with the first openings 57 corresponding to the larger volumes and second openings 58 corresponding to smaller volumes. Then, as seen in FIG. 5F, a second copper etch may be performed removing the lower copper layer 53 under the holes 57 and the upper copper layer 55 under the holes 58 and the second photoresist layer 57 may be removed.

Then, as seen in FIG. 5G, the upper copper layer 55 may be thickened to create a thicker upper copper layer 58. The thicker copper layer 58 may provide additional mechanical support for the film stack to help minimize the risk of collapse during etching and drying steps. The thickened copper layer 58 may be approximately 1-5 microns thick.

Then, as seen in FIG. 5H, a second chromium etch may be performed removing the lower chromium layer 52 from under the holes 57 and the upper chromium layer 54 from under the holes 58.

Then, as seen in FIG. 5I, a first glass etch may be performed so that the glass under the holes 57 may be partially etched. The first glass etch may be followed by a second copper etch (FIG. 5J) and a second chromium etch (FIG. 5K). Then, as seen in FIG. 5L, a second glass etch may be performed so that the glass under the holes 57 may he further etched and the glass under the holes 58 may be etched. After the film stack is removed, the glass mold having multiple volumes is completed (FIG. 5M).

Where there are to be more than two different sized volumes, additional copper/chromium layers may be used and additional copper/chromium/glass etch steps may be performed until all volumes are fully etched to their respective desired volumes.

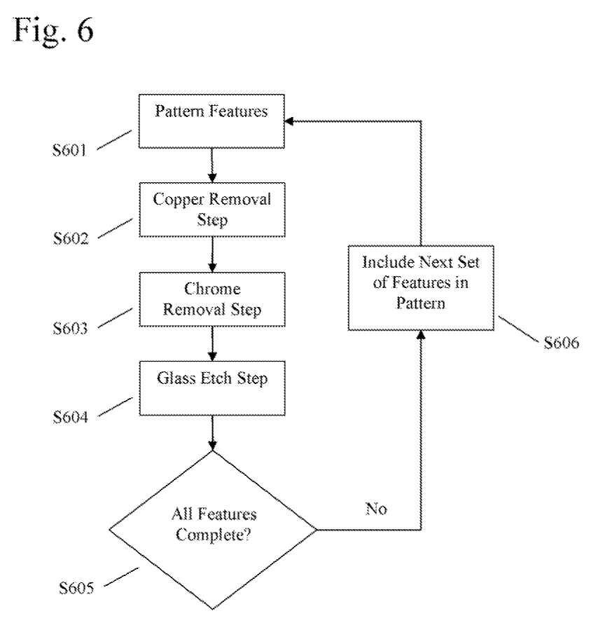

This process is illustrated in FIG. 6. First, a substrate layered with alternating layers of chromium and copper (one such set of layers for each cavity size) is patterned (Step S601). The patterning step includes applying a masking layer and then patterning the mask. The first time patterning occurs; patterning is performed for the openings corresponding to the largest cavities. Then, copper etch (Step S602) may be performed. The mask may be removed at any point in this process but may be removed, for example between the copper etch (Step S602) and a chromium etch (Step 603). Next, chromium etch (Step S603) may be performed. Then, a glass etch step may be performed (Step S604) to begin substrate etch for the largest cavities.

If all cavities have been fully etched (yes, Step S605) then the process is complete. However, if all cavities have not been fully etched (no, Step S605) then a new mask is applied (Step S601) such that all previously patterned openings are opened again along with the next-largest set of cavities (Step S606). This process continues until all cavities are fully etched. Because of the layered approach, the first glass etch step only etches the largest cavity, the next glass etch step further etches the largest cavity and begins etching the next-largest cavity, additional glass etch steps proceed accordingly until all cavities have been fully etched. The length of time the glass etch steps are performed for are calculated according to the desired etch volume for each cavity.

According to this approach, where there are cavities of two sizes, the larger cavity will be etched twice and the smaller cavity will be etched once, as illustrated above with reference to FIGS. 5(A-M). Where there are cavities of three sizes, the largest cavity will be etched three times, the middle cavity will be etched twice and the smallest cavity will be etched once. The duration for each etch step may be calculated accordingly, and each etch step need not have equal duration. By varying the duration of each etch step, the desired volume of the cavities may be achieved.

Because the top layer may be the copper layer, at some point in the process, for example, after the first copper etch (Step S602), the top copper layer may be thickened. The thickened copper layer may provide enhanced structural support for the film stacks and may minimize the risk of the film stacks collapsing during glass etch.

The above specific exemplary embodiments are illustrative, and many variations can be introduced on these embodiments without departing from the spirit of the disclosure or from the scope of the appended claims. For example, elements and/or features of different exemplary embodiments may be combined with each other and/or substituted for each other within the scope of this disclosure and appended claims.

1. A method for fabricating a solder transfer mold, comprising:
masking a substrate with a masking agent;
transferring a pattern to the substrate mask;
etching the masked substrate until cavities of a first volume are formed;
selectively coating the cavities of the first volume; and
etching the masked substrate until cavities of a second volume are formed.

2. The method of claim 1, additionally comprising:
selectively coating the cavities of the first volume; and
etching the masked substrate until cavities of a third volume are formed.

3. The method of claim 1, additionally comprising repeating the steps of selectively coating fully etched cavities and continuing to etch not-fully etched cavities until all cavities are fully etched.

4. The method of claim 1, additionally comprising removing the selective coatings.

5. The method of claim 1, wherein the selective coatings comprise metal.

6. The method of claim 1, wherein the selective coatings comprise a polymer.

7. The method of claim 6, wherein the selective coating comprising the polymer is cured after each application and prior to resumption of etching.

8. The method of claim 1, wherein the substrate comprises glass.

9. A method for fabricating a solder transfer mold, comprising:
covering a substrate having anisotropic etching properties with a masking layer;
patterning the masking layer to create a plurality of openings of at least two different sizes; and
etching the substrate through the patterned mask to generate a plurality of cavities of at least two different volumes.

10. The method of claim 9, wherein the substrate comprises crystalline silicon.

11. The method of claim 9, wherein the plurality of openings are each square-shaped or rectangle-shaped.

12. The method of claim 9, wherein the step of covering the substrate with a masking layer comprises oxidizing a top surface of the substrate.

13-17. (canceled)

18. A method for applying solder bumps directly to an integrated circuit, comprising:
filling a plurality of cavities within a solder mold with solder;
placing the solder mold in proximity with the integrated circuit; and
transferring the solder from the pluralities of the cavities to the integrated circuit, wherein the solder mold comprises a substrate and the plurality of cavities and the plurality of cavities comprises cavities of at least two different volumes.

19. The method of claim 18, wherein the substrate comprises glass.

20. The method of claim 18, wherein the substrate comprises crystalline silicon having anisotropic etching properties

21. A method for fabricating a solder transfer mold having solder cavities of multiple different volumes, comprising:
placing multiple alternating layers of a first protective material and a second protective material on a substrate; and
repeating the etch steps of:
performing a first protective material etch;
performing a second protective material etch; and
performing a substrate etch;
wherein the number of alternating layer pairs is equal to the number of etch step repetitions and is equal to the number of different volumes.

22. The method of claim 21, wherein the first protective materials is chromium and the second protective materials is copper.

23. The method of claim 22, wherein a top protective material layer is copper and the top copper layer is thickened after the first copper etch.

24. The method of claim 21, wherein the substrate is glass.

25. The method of claim 21, wherein, for each etch repetition, prior to performing the first protective material etch, a mask is used, and the first time a mask is used, the mask reveals openings for a first set of solder cavities, and each additional time a mask is used, the mask reveals all of the previously revealed openings as well as an additional set of openings for an additional set of solder cavities.

26. A method for generating a solder mold, comprising:
etching a first set of cavities of a first volume in a solder mold substrate; and
continuing to etch the first set of cavities while etching a second set of cavities of a second volume, the second volume being smaller than the first volume.

27. The method of claim 26, further comprising:
continuing to etch the first set of cavities and the second set of cavities while etching a third set of cavities of a third volume, the third volume being smaller than the second volume.

28. The method of claim 27, further comprising:
continuing to etch the first set of cavities, the second set of cavities and the third set of cavities while etching a fourth set of cavities of a fourth volume, the fourth volume being smaller than the third volume.
